(19) United States
(12) Patent Application Publication
(10) Pub. No.: US 2012/0132938 A1
(43) Pub. Date: May 31, 2012

(54) LED PACKAGE

(75) Inventors: Tetsuro Komatsu, Fukuoka-ken (JP); Satoshi Shimizu, Fukuoka-ken (JP)

(73) Assignee: KABUSHIKI KAISHA TOSHIBA, Tokyo (JP)

(21) Appl. No.: 13/052,255

(22) Filed: Mar. 21, 2011

(30) Foreign Application Priority Data
Nov. 29, 2010 (JP) 2010-265310

(51) Int. Cl. H01L 27/15

(52) U.S. Cl. 257/89; 257/E27.12

(57) ABSTRACT

According to one embodiment, an LED package includes a first, a second, and a third lead frame separated from one another. The LED package includes a first LED chip of a top surface terminal type having one terminal connected to the second lead frame, and having one other terminal connected to the third lead frame, the first LED chip is mounted on the first lead frame. The LED package includes a first protection chip of a top surface terminal type having one terminal connected to the second lead frame, and having one other terminal connected to the third lead frame, the first protection chip is mounted on the first lead frame. And, a resin body covers a part of the first, second and third lead frames, the first LED chip, and the first protection chip, An outer shape of the resin body forms an outer shape of the LED package.

### CROSS-REFERENCE TO RELATED APPLICATIONS

This application is based upon and claims the benefit of priority from the prior Japanese Patent Application No. 2010-265310, filed on Nov. 29, 2010; the entire contents of which are incorporated herein by reference.

### FIELD

Embodiments described herein relate generally to a LED package.

### BACKGROUND

Conventionally, in an LED package that mounts LED chips, a bowl-shaped envelope formed of white resin has been provided, the LED chips have been mounted on a bottom surface of the envelope, and transparent resin has been encapsulated inside the envelope to embed the LED chips for the purpose of controlling a light distribution characteristic to increase light extraction efficiency from the LED package. Additionally, the envelopes have been formed of polyamide series thermoplastic resin in many cases. However, in recent years, further reduction in size of the LED packages has been requested along with an expanding application range of the LED packages.

### BRIEF DESCRIPTION OF THE DRAWINGS

FIG. 1 is a perspective view illustrating an LED package according to a first embodiment;

FIG. 2A is a plan view illustrating the LED package according to the embodiment, and FIG. 2B is a cross-sectional view taken along a line A-A′ shown in FIG. 2A;

FIG. 3 is a flow chart illustrating a method for manufacturing the LED package according to the embodiment;

FIGS. 4A to 6B are cross-sectional views of processes illustrating the method for manufacturing the LED package according to the embodiment;

FIG. 7A is a plan view illustrating a lead frame sheet in the embodiment, and FIG. 7B is a partial enlarged plan view illustrating an element region of this lead frame sheet;

FIGS. 8A to 8H are cross-sectional views of processes illustrating a method for forming the lead frame sheet in a variation of the first embodiment;

FIG. 9 is a plan view illustrating an LED package according to a second embodiment;

FIG. 10 is a perspective view illustrating an LED package according to a third embodiment;

FIG. 11 is a side view illustrating the LED package according to the third embodiment; and

FIG. 12A is a plan view illustrating lead frames, LED chips, and wires of an LED package according to a fourth embodiment, FIG. 12B is a bottom surface view illustrating the LED package, and FIG. 12C is a cross-sectional view illustrating the LED package.

### DETAILED DESCRIPTION

In general, according to one embodiment, an LED package includes a first, a second, and a third lead frame separated from one another. The LED package includes a first LED chip of a top surface terminal type having one terminal connected to the second lead frame, and having one other terminal connected to the third lead frame, the first LED chip is mounted on the first lead frame. The LED package includes a first protection chip of a top surface terminal type having one terminal connected to the second lead frame, and having one other terminal connected to the third lead frame, the first protection chip is mounted on the first lead frame. And, a resin body covers a part of the first, second and third lead frames, the first LED chip, and the first protection chip, An outer shape of the resin body forms an outer shape of the LED package.

Various embodiments will be described hereinafter with reference to the accompanying drawings.

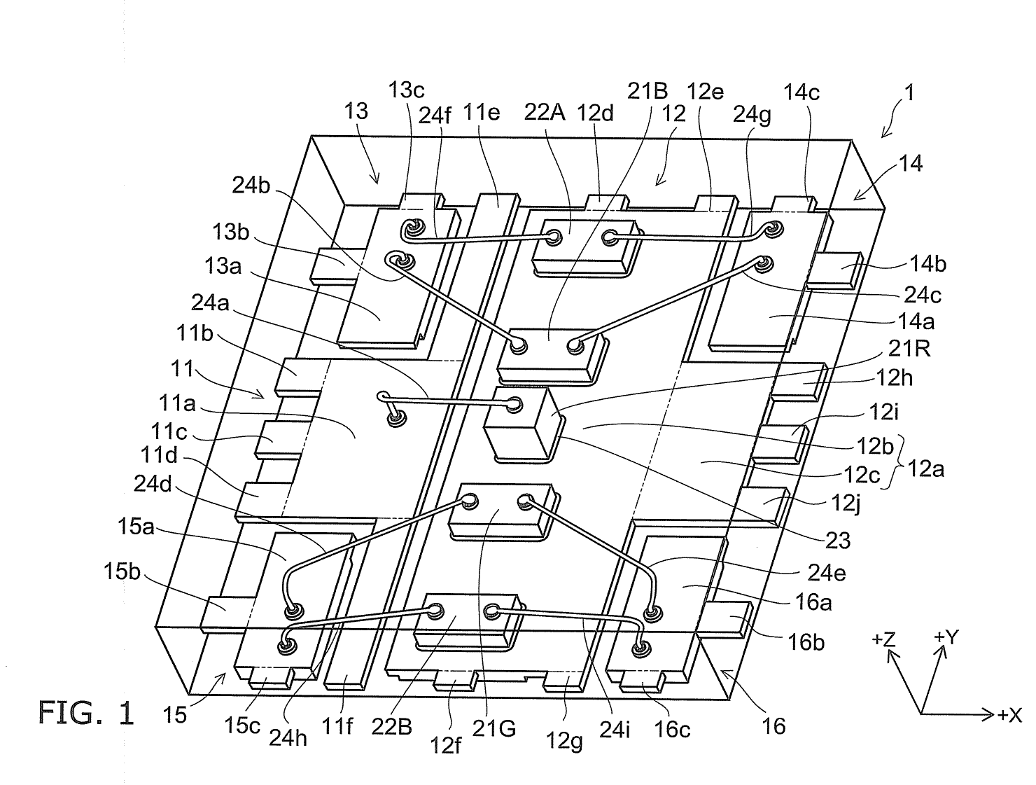

First, a first embodiment will be described. FIG. 1 is a perspective view illustrating an LED package according to the embodiment.

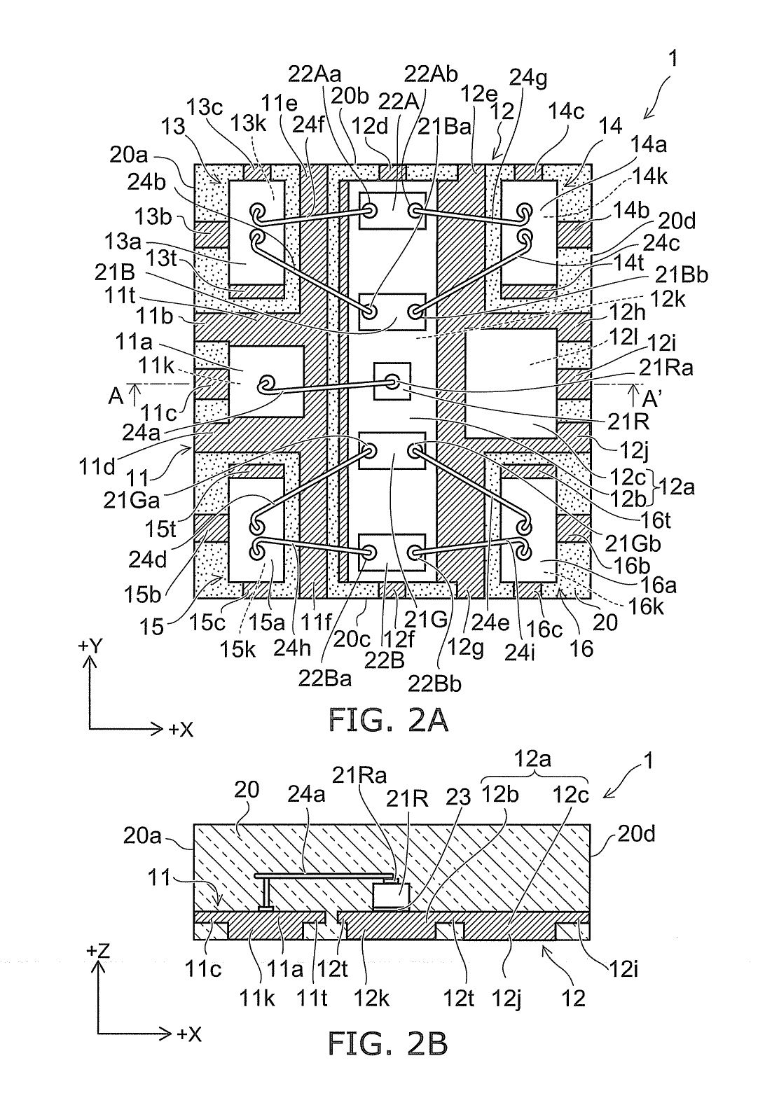

FIG. 2A is a plan view illustrating the LED package according to the embodiment, and FIG. 2B is a cross-sectional view taken along a line A-A′ shown in FIG. 2A.

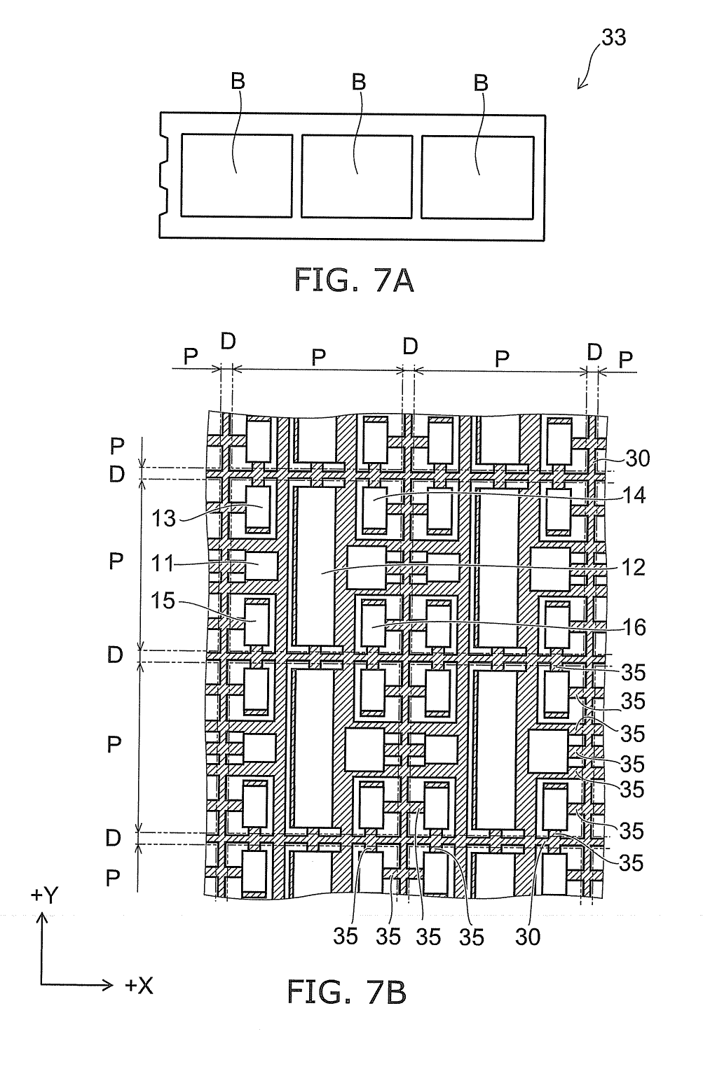

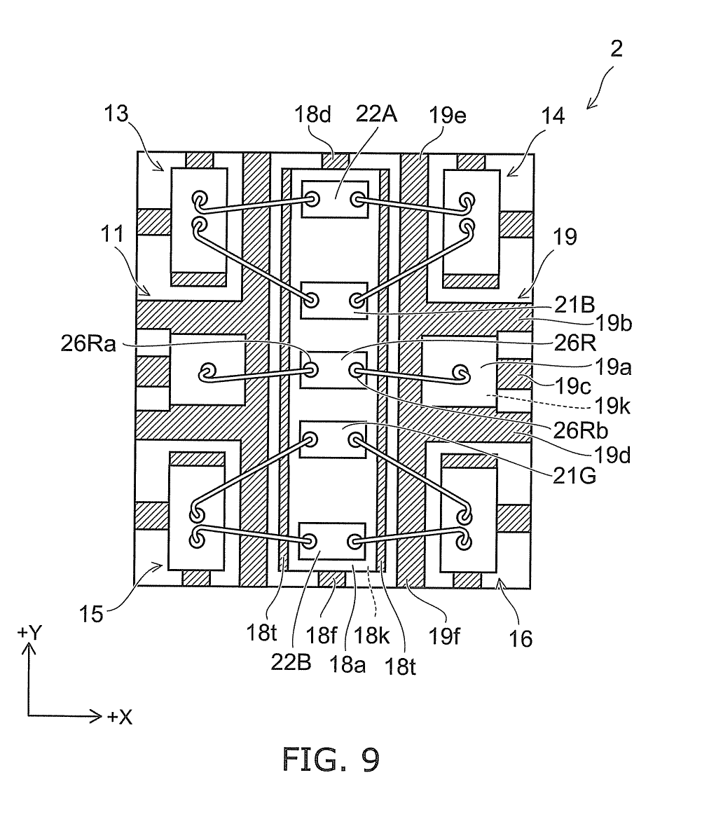

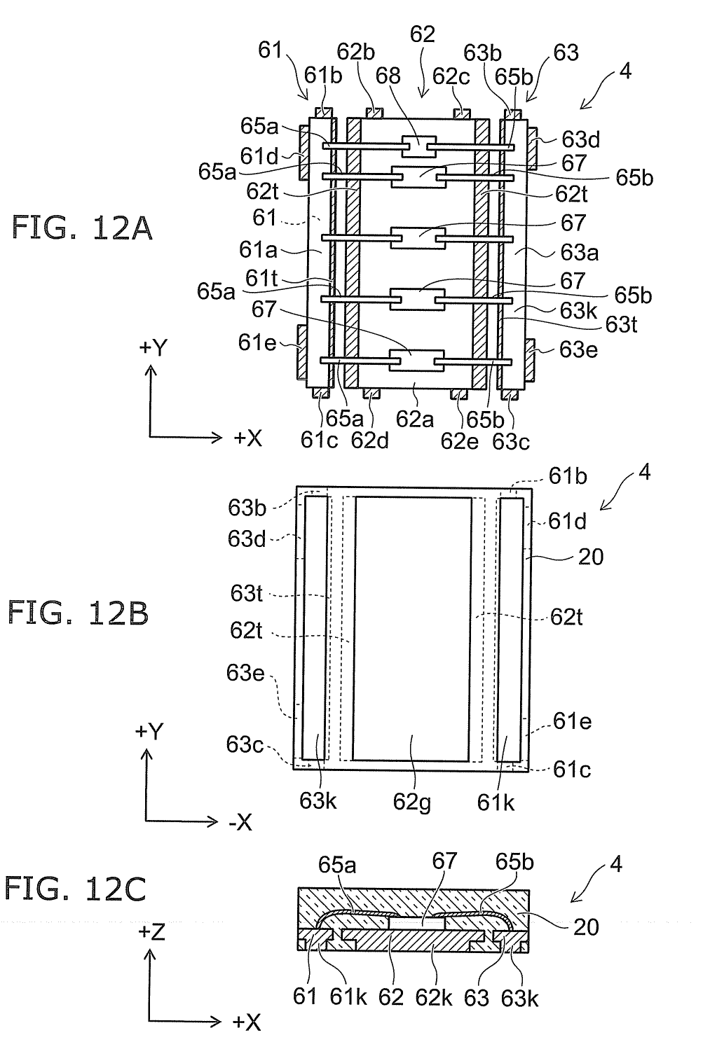

It is to be noted that for convenience of illustration, boundaries between bases and extending portions, and boundaries between rectangular portions in the bases are shown by chain double-dashed lines in FIG. 1. In addition, thin plate portions are shown marked with oblique lines in FIG. 2A. FIG. 7B, FIG. 9, and FIG. 12A, which will be described hereinafter, are also similar to this. Further, regions with no lead frames are shown marked with dots in FIG. 2A. FIG. 9, which will be described hereinafter, is also similar to this.

As shown in FIG. 1, and FIGS. 2A and 2B, six lead frames 11 to 16 are provided in an LED package 1 according to the embodiment. A shape of the lead frames 11 to 16 is a plate-like one, and they are arranged on a same plane and are separated from one another. The lead frames 11 to 16 are comprised of a same conductive material and, for example, they are configured such that silver plating layers are formed on top surfaces and bottom surfaces of copper plates. It is to be noted that the silver plating layers are not formed on end surfaces of the lead frames 11 to 16, but the copper plates are exposed.

Three LED chips 21R, 21G, and 21B, and two protection chips 22A and 22B are mounted on the lead frame 12. The LED chip 21R is a vertical conduction type chip that emits red light, the LED chip 21G is a top surface terminal type chip that emits green light, and the LED chip 21B is a top surface terminal type chip that emits blue light. In addition, the protection chips 22A and 22B are top surface terminal type electrostatic protection chips, and ZDs (Zener diodes) are formed thereinside. In the vertical conduction type chip, one terminal is provided on each of a top surface and a bottom surface thereof. In the top surface terminal type chip, two terminals are provided on a top surface thereof.

In addition, in the LED package 1, provided is a transparent resin body 20 with which the respective whole top surfaces, parts of the bottom surfaces, and parts of the end surfaces of the lead frames 11 to 16 are covered, with which the LED chips 21R, 21G, and 21B are covered, with which the protection chips 22A and 22B are covered, and without which the respective remained portions of the bottom surfaces and remained portions of the end surfaces of the lead frames 11 to 16 are exposed. The transparent resin body 20 is formed of transparent resin, for example, silicone resin. It is to be noted that “transparent” also means being translucent. An outer shape of the transparent resin body 20 is a rectangular parallelepiped, and therefore, a shape thereof is a rectangle when viewed from a Z direction. Additionally, the outer shape of the transparent resin body 20 forms an outer shape of the LED package 1.

Hereinafter, in the specification, an XYZ orthogonal coordinate system will be introduced for convenience of description. Defined to be a +X direction is a direction from the lead frame 11 toward the lead frame 12 among directions parallel to the top surfaces of the lead frames 11 to 16, defined to be a +Z direction is an upward direction, i.e., a direction from the lead frames toward the LED chips among directions vertical to the top surfaces of the lead frames 11 to 16, and defined to be a +Y direction is one of directions perpendicular to both the +X direction and the +Z direction. It is to be noted that defined to be a −X direction, a −Y direction, and a −Z direction, respectively are directions opposite to the +X direction, the +Y direction, and the +Z direction. In addition, for example, the “+X direction” and the “−X direction” are collectively simply referred to as an “X direction”.

In the respective lead frames 11 to 16, provided are one base and a plurality of extending portions extending from the base to the X direction or a Y direction. The base and the extending portions are integrally formed in the each lead frame. The each base is separated from side surfaces 20a to 20d of the transparent resin body 20, and a tip surface of the each extending portion is exposed at the side surfaces 20a to 20d of the transparent resin body 20. In addition, a bottom surface of the each base includes a protruding portion, and a portion of the each base where the protruding portion is not formed is a thin plate portion.

The top surfaces of the lead frames 11 to 16 constitute parts of a same XY plane. In addition, the extending portions of the lead frames 11 to 16 and bottom surfaces of the thin plate portions also constitute parts of another same XY plane. Further, bottom surfaces of the protruding portions of the lead frames 11 to 16 also constitute parts of a still another same XY plane. Namely, all the extending portions and the thin plate portions are arranged in a same layer whose top surface and bottom surface are parallel to the XY plane, and a thickness of the extending portions and that of the thin plate portions are the same as each other. Hence, each lead frame has two levels of plate thicknesses. When viewed from the Z direction, a region of the each base where the protruding portion is formed is a thick plate portion (a first plate portion) where the plate thickness is relatively large, and a region of the base on which the thin plate portion and the extending portions are formed is a thin plate portion (a second plate portion) where the plate thickness is relatively small.

Additionally, among the bottom surfaces of the each lead frame, the bottom surface of the thick plate portion i.e., only the bottom surface of the protruding portion is exposed at the bottom surface of the transparent resin body 20, and the other region on the bottom surface of the each lead frame is covered with the transparent resin body 20. Namely, the bottom surfaces of the thin plate portions and the extending portions are covered with the transparent resin body 20. In addition, only the tip surfaces of the extending portions among the end surfaces of the each lead frame are exposed at the side surfaces of the transparent resin body 20, and the other region is covered with the transparent resin body 20. Namely, the end surfaces of the base, the side surfaces of the protruding portion, and the side surfaces of the extending portions are covered with the transparent resin body 20. Further, whole regions of the top surfaces of the lead frames 11 to 16 are covered with the transparent resin body 20. Additionally, the bottom surface of the protruding portion of the each lead frame serves as an external electrode pad of the LED package 1. It is to be noted that in the specification, “cover” is a concept including both cases where something to cover with is in contact with something to be covered, and where it is not in contact with it.

Hereinafter, a planar layout of the lead frames 11 to 16 will be described. As shown in FIG. 1, and FIGS. 2A and 2B, the layout of the lead frames 11 to 16 is symmetrical about an XZ plane that passes through a center of the LED package 1. The lead frame 11 is arranged in a center of the Y direction in a side end of the −X direction of the LED package 1, and the lead frame 12 is arranged along an entire length of the Y direction in a center of the X direction of the LED package 1, and in a center of the Y direction in a side end of the +X direction of the LED package 1. The lead frames 13, 14, 15, and 16 are arranged at a corner of a −X and +Y direction side of the LED package 1, a corner of a +X and +Y direction side, a corner of a −X and −Y direction side, and a corner of a +X and −Y direction side, respectively.

The lead frame 11 is provided with a rectangular base 11a when viewed from the Z direction, and five extending portions 11b, 11c, 11d, 11e, and 11f extend from this base 11a. The extending portions 11b, 11c, and 11d extend toward the −X direction from an end of a +Y direction side, a center of the Y direction, and an end of a −Y direction side of an end edge oriented to the −X direction of the base 11a, respectively, and tip surfaces of the extending portions 11b, 11c, and 11d are exposed at a side surface 20a oriented to the −X direction of the transparent resin body 20. The extending portion 11e extends toward the +Y direction from an end of the +X direction side of an end edge oriented to the Y direction of the base 11a, passes through between the lead frames 13 and 12, and a tip surface of the extending portion 11e is exposed at a side surface 20b oriented to the +Y direction in the transparent resin body 20. The extending portion 11f extends toward the −Y direction from the end of the +X direction side of an end edge oriented to the −Y direction of the base 11a, passes through between the lead frames 15 and 12, and a tip surface of the extending portion 11f is exposed at a side surface 20c oriented to the −Y direction in the transparent resin body 20. Hence, an end edge oriented to the +X direction in the lead frame 11 linearly extends along the entire length of the Y direction of the transparent resin body 20. In addition, a bottom surface of the base 11a includes a protruding portion 11k, and a portion of the base 11a where the protruding portion 11k is not formed is a thin plate portion 11t. When viewed from the Z direction, a shape of the protruding portion 11k is a rectangle, and a shape of the thin plate portion 11t is a U-shaped one open to the −X direction.

The lead frame 12 is provided with a protruding-shaped base 12a oriented to the +X direction when viewed from the Z direction. Namely, the base 12a is provided with: a rectangular portion 12b that is arranged in a region including a center of the LED package 1 when viewed from the Z direction, and that extends along the entire length of the Y direction of the transparent resin body 20; and a rectangular portion 12c whose length in the Y direction is smaller than that of the rectangular portion 12b, and equal to that of the base 11a of the lead frame 11, the rectangular portion 12c being arranged at the +X direction side of the rectangular portion 12b, and being continuous with the rectangular portion 12b.

Seven extending portions 12d to 12j extend from the base 12a. The extending portions 12d and 12e extend toward the +Y direction from a center of the X direction, and an end of the +X direction side in an end edge oriented to the +Y direction of the rectangular portion 12b, and tip surfaces of the extending portions 12d and 12e are exposed at the side surface 20b oriented to the +Y direction of the transparent resin body 20. The extending portions 12f and 12g extend toward the −Y direction from a center of the X direction, and an end of the +X direction side in an end edge oriented to the −Y direction of the rectangular portion 12b, and tip surfaces of the extending portions 12f and 12g are exposed at the side surface 20c oriented to the −Y direction of the transparent resin body 20. The extending portions 12h, 12i, and 12j extend toward the +X direction from an end of the +Y direction side, a center of the Y direction, and an end of the −Y direction side in an end edge oriented to the +X direction of the rectangular portion 12c, and tip surfaces of the extending portions 12h, 12i, and 12j are exposed at a side surface 20d oriented to the +X direction of the transparent resin body 20. Hence, an end edge oriented to the −X direction in the lead frame 12 linearly extends along the entire length of the Y direction of the transparent resin body 20.

In addition, bottom surfaces of the rectangular portions 12b and 12c include protruding portions 12k and 12l which are formed separated from each other, respectively. When viewed from the Z direction, shapes of the protruding portions 12k and 12l are rectangles, respectively. A portion of the base 12a where the protruding portions 12k and 12l are not formed is a thin plate portion 12t. The thin plate portion 12t is provided at the −X and the +X direction sides of the protruding portion 12k, and between the protruding portions 12k and 12l, and the +Y and the −Y direction sides of the protruding portion 12l. Hence, a bottom surface of the lead frame 12 includes the protruding portion 12k, the region being separated from both an end edge opposed to the lead frame 13 and an end edge opposed to the lead frame 14.

The lead frame 13 is provided with one base 13a, and two extending portions 13b and 13c extend from this base 13a. When viewed from the Z direction, a shape of the base 13a is a rectangle in which the Y direction corresponds to a longitudinal direction. The extending portion 13b extends toward the −X direction from a center of the Y direction in an end edge oriented to the −X direction of the base 13a, and a tip surface of the extending portion 13b is exposed at the side surface 20a of the transparent resin body 20. The extending portion 13c extends toward the +Y direction from a center of the X direction in an end edge oriented to the +Y direction of the base 13a, and a tip surface of the extending portion 13c is exposed at the side surface 20b of the transparent resin body 20. A bottom surface of the base 13a includes a protruding portion 13k in a region except an end of the −Y direction side, and a portion of the base 13a where the protruding portion 13k is not formed, i.e., the end of the −Y direction side is a thin plate portion 13t. When viewed from the Z direction, shapes of the protruding portion 13k and a thin plate portion 13t are rectangles, respectively.

A shape of the lead frame 14 is a mirror image of the lead frame 13 with respect to a YZ plane that passes through the center of the LED package 1. Namely, the lead frame 14 is provided with one base 14a and two extending portions 14b and 14c, and the lead frame 14 includes a protruding portion 14k and a thin plate portion 14t.

Shapes of the lead frames 15 and 16 are respectively mirror images of the lead frames 13 and 14 with respect to the XZ plane that passes through the center of the LED package 1. It is to be noted that the shape of the lead frame 14 is not limited to the mirror image of the lead frame 13, and the shapes of the lead frames 15 and 16 are not limited to the mirror images of the lead frames 13 and 14.

The above-described LED chips 21R, 21G, and 21B and protection chips 22A and 22B are mounted on the rectangular portion 12b of the base 12a of the lead frame 12 through a die mount material 23, and they are arranged in a region above the protruding portion 12k. The protection chip 22A, the LED chips 21B, 21R, 21G, and the protection chip 21B are aligned in a line in this order from the end of the +Y direction side toward the end of the −Y direction side of the rectangular portion 12b. When viewed from the Z direction, the LED chip 21R is arranged in a region including the center of the LED package 1. In addition, each top surface terminal type chip, i.e., the LED chips 21B and 21G and the protection chips 22A and 22B, are aligned so that longitudinal directions thereof may correspond to the X direction, and a pair of terminals provided on a top surface of the each chip is aligned along the X direction.

A top surface terminal 21Ra of the LED chip 21R is connected to the lead frame 11 through a wire 24a, and a bottom surface terminal (not shown) is connected to the lead frame 12 through the conductive die mount material 23. One terminal 21Ba provided on a top surface of the LED chip 21B is connected to the lead frame 13 through a wire 24b, and the other terminal 21Bb is connected to the lead frame 14 through a wire 24c. One terminal 21Ga provided on a top surface of the LED chip 21G is connected to the lead frame 15 through a wire 24d, and the other terminal 21Gb is connected to the lead frame 16 through a wire 24e.

One terminal 22Aa of the protection chip 22A is connected to the lead frame 13 through a wire 24f, and the other terminal 22Ab is connected to the lead frame 14 through a wire 24g. Namely, the protection chip 22A is connected in parallel to the LED chip 21B. In addition, one terminal 22Ba of the protection chip 22B is connected to the lead frame 15 through a wire 24h, and the other terminal 22Bb is connected to the lead frame 16 through a wire 24i. Namely, the protection chip 22B is connected in parallel to the LED chip 21G. The die mount material 23 is, for example, formed of silver paste or solder, and the wires 24a to 24i are, for example, formed of gold or aluminum.

As for the wires 24a to 24i (hereinafter collectively also referred to as a “wire 24”), an angle between a direction to which the wire 24 is pulled out from an end joined to the terminal of the each chip and the XY plane (hereinafter referred to as a “chip side pull-out angle”) is smaller than an angle between a direction to which the wire 24 is pulled out from an end joined to the lead frame and the XY plane (hereinafter referred to as a “frame side pull-out angle”). For example, the chip side pull-out angle is 0 to 5 degree(s), and the frame side pull-out angle is 85 to 90 degrees. In addition, a portion other than both ends of the wire 24 is displaced toward the center of the LED package 1 when viewed from a region directly above a straight line connecting these both ends.

Specifically, portions other than both ends of the wires 24f and 24g connected to the protection chip 22A are located at the −Y direction side when viewed from straight lines connecting these both ends. Portions other than both ends of the wires 24b and 24c connected to the LED chip 21B are located at the −Y direction side when viewed from straight lines connecting these both ends. Meanwhile, portions other than both ends of the wires 24h and 24i connected to the protection chip 22B are located at the +Y direction side when viewed from straight lines connecting these both ends. Portions other than both ends of the wires 24d and 24e connected to the LED chip 21G are also located at the +Y direction side when viewed from straight lines connecting these both ends.

As described above, on the each of the six lead frames 11 to 16, provided is/are one or more extending portion(s) whose tip surface(s) is/are exposed at the side surface 20b or 20c of the transparent resin body 20, the extending portion(s) extending in the Y direction. In addition, provided is/are one or more extending portion(s) whose tip surface(s) is/are exposed at the side surface 20a or 20d of the transparent resin body 20, the extending portion(s) extending in the X direction. Hence, on these lead frames, provided is a plurality of extending portions whose tip surfaces are exposed at the two side surfaces perpendicular to each other in the transparent resin body 20. Particularly, the tip surfaces of the extending portions 12d to 12j of the lead frame 12 on which the LED chips 21R, 21B, and 21G and the protection chips 22A and 22B are mounted are exposed at the three side surfaces 20b, 20c, and 20d different from one another of the transparent resin body 20.

Next will be described a method for manufacturing the LED package according to the embodiment.

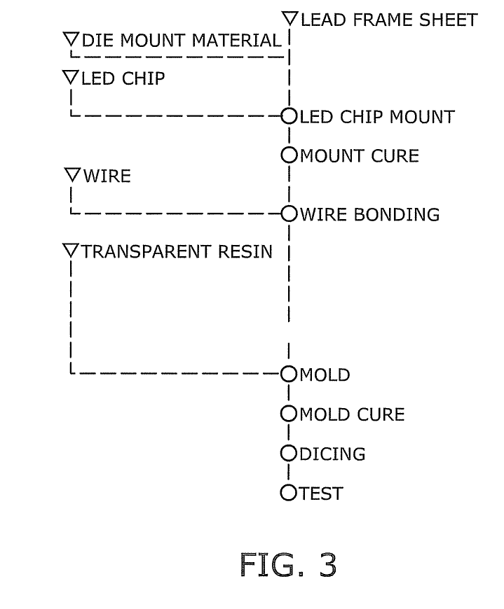

FIG. 3 is a flow chart illustrating the method for manufacturing the LED package according to the embodiment.

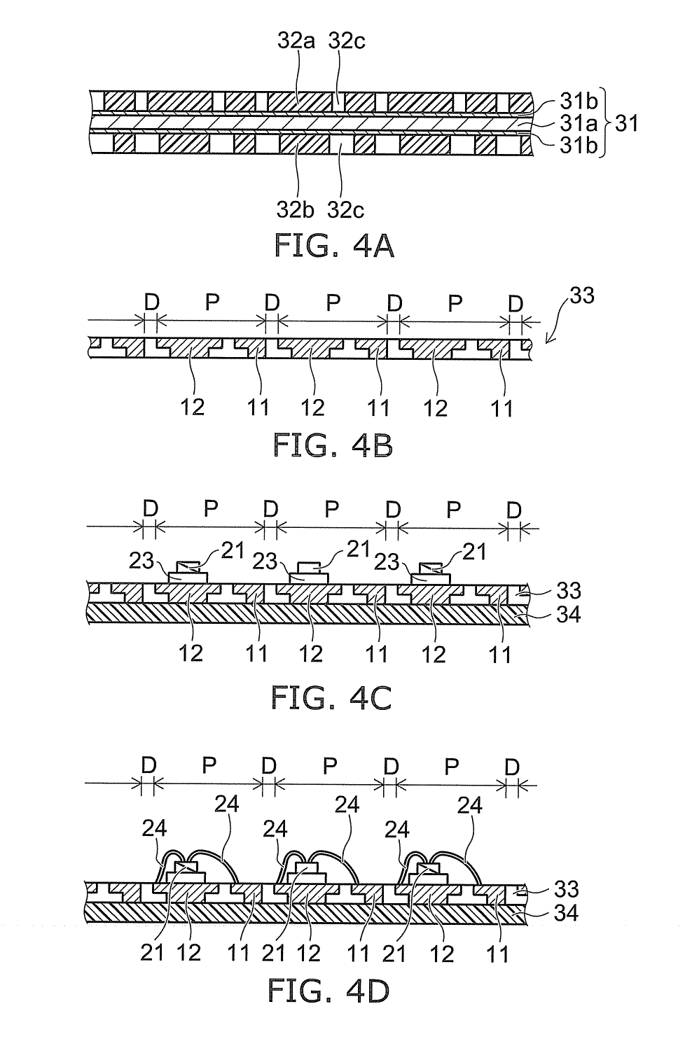

FIGS. 4A to 4D, FIGS. 5A to 5C, and FIGS. 6A and 6B are cross-sectional views of processes illustrating the method for manufacturing the LED package according to the embodiment.

FIG. 7A is a plan view illustrating a lead frame sheet in the embodiment, and FIG. 7B is a partial enlarged plan view illustrating an element region of this lead frame sheet.

It is to be noted that a structure of the each LED package is simply depicted for convenience of illustration in FIGS. 4A to 4D to FIGS. 7A and 7B. For example, LED chips are collectively referred to as an LED chip 21, wires are collectively referred to as the wire 24, and illustrations of the protection chips 22A and 22B (hereinafter also collectively referred to as a “protection chip 22”) are omitted. In addition, thin plate portions are shown marked with oblique lines in FIG. 7B.

First, as shown in FIG. 4A, a conductive sheet 31 comprised of a conductive material is prepared. This conductive sheet 31 is, for example, formed by applying silver plating layers 31b to top and bottom surfaces of a strip-shaped copper plate 31a. Next, masks 32a and 32b are formed on top and bottom surfaces of this conductive sheet 31, respectively. Openings 32c are selectively formed on the masks 32a and 32b. The masks 32a and 32b can be formed, for example, by a printing method.

Next, the conductive sheet 31 is wet-etched by immersing in an etchant the conductive sheet 31 on which the masks 32a and 32b are deposited. As a result of this, portions located inside the openings 32c of the conductive sheet 31 are etched to be selectively removed. At this time, for example, an etching amount is controlled by adjusting an immersing time, and etching is stopped before the etching from a top surface side and a bottom surface side of the conductive sheet 31 respectively independently penetrate the conductive sheet 31. As a result of this, half etching is performed from the top and bottom surfaces side. However, portions etched from both the top surface side and the bottom surface side are made to penetrate the conductive sheet 31. Subsequently, the masks 32a and 32b are removed.

As a result of this, as shown in FIGS. 3 and 4B, the copper plate 31a and the silver plating layers 31b are selectively removed from the conductive sheet 31, and then a lead frame sheet 33 is formed. It is to be noted that for convenience of illustration, the copper plate 31a and the silver plating layers 31b are not distinguished from each other, but they are integrally depicted as the lead frame sheet 33 in the drawings subsequent to FIG. 4B.

As shown in FIG. 7A, for example, three blocks B are set on the lead frame sheet 33, and for example, approximately 1000 element regions P are set in the each block B. In addition, a target mark (not shown) used for alignment in a latter process is formed on the lead frame sheet 33.

As shown in FIG. 7B, the element regions P are aligned in a matrix form, and spaces between the element regions P are lattice-shaped dicing regions D. The conductive material forming the conductive sheet 31 is completely removed from the regions etched from both the top surface side and the bottom surface side of the lead frame sheet 33, and the regions become penetration regions. In addition, only a bottom portion of the conductive sheet 31 is removed from regions etched only from the bottom surface side of the lead frame sheet 33, and the regions become thin plate portions. Further, the conductive sheet 31 completely remains in regions etched from neither the top surface side nor the bottom surface side of the lead frame sheet 33, and the regions become thick plate portions. In a manner described above, a basic pattern including the six lead frames 11 to 16 separated from one another is formed in the each element region P. In addition, lattice-shaped support members 30 are formed in the dicing regions D.

Each lead frame is provided with: a base separated from an outer edge of the element region P; and coupling portions 35 that extend from the base, reach the outer edge of the element region P, and are coupled with the support member 30. Among the coupling portions 35 provided on the each lead frame, some coupling portions 35 extend in the X direction to reach a side extending in the Y direction of the outer edge of the element region P, and the remaining coupling portions 35 extend in the Y direction to reach a side extending in the X direction of the outer edge of the element region P. Namely, the plurality of coupling portions 35 provided on the six lead frames connected to the LED chips has reached the two sides perpendicular to each other of the outer edge of the element region P.

Next, as shown in FIGS. 3 and 4C, a reinforcing tape 34 formed of, for example, polyimide, is applied on the bottom surface of the lead frame sheet 33. The die mount material 23 is then deposited on the lead frame 12 belonging to the each element region P of the lead frame sheet 33. Next, the LED chips 21R, 21G, and 21B and the protection chips 22A and 22B are mounted on the die mount material 23. Next, heat treatment (mount cure) for sintering the die mount material 23 is performed. As a result of this, the LED chips 21R, 21G, and 21B and the protection chips 22A and 22B are mounted on the lead frame 12 through the die mount material 23 in the each element region P of the lead frame sheet 33.

Next, as shown in FIGS. 3 and 4D, one end of the wire 24 is joined to the top surface of the each lead frame by, for example, ultrasonic joining. Subsequently, the wire 24 is pulled out from this joined portion nearly to an upper side (+Z direction), bent nearly to a right angle, and nearly horizontally pulled out to an upper side of the each LED chip 21 or protection chip 22. The other end of the wire 24 is then joined to the terminal of the each LED chip or protection chip. A vibration direction of ultrasonic waves is defined to be, for example, the Y direction in the above-described ultrasonic joining. As a result of this, each terminal provided on the top surface of the each LED chip is connected to the each lead frame through the wire 24.

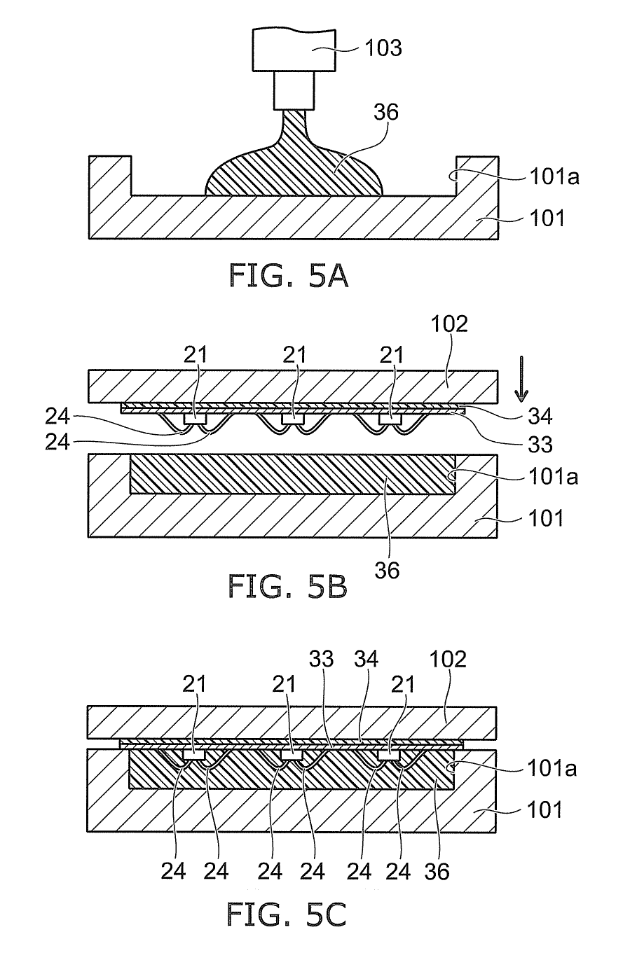

Next, as shown in FIGS. 3 and 5A, a lower mold 101 is prepared. The lower mold 101 constitutes a pair of molds together with an upper mold 102 that will be described hereinafter, and a rectangular-parallelepiped-shaped depression portion 101a is formed on a top surface of the lower mold 101. Meanwhile, a liquid or a semi-liquid resin material 36 is prepared with transparent resin, such as silicone. It is to be noted that at this time, a diffusing agent may be added to the resin material 36. The resin material 36 is then supplied in the depression portion 101a of the lower mold 101 by a dispenser 103.

Next, as shown in FIGS. 3 and 5B, the lead frame sheet 33 having the above-described LED chips 21 mounted thereon is attached on a bottom surface of the upper mold 102 so that the LED chips 21 may be oriented downward. As shown in FIG. 5C, the upper mold 102 is pressed against the lower mold 101, and the mold is clamped. As a result of this, the lead frame sheet 33 is pressed against the resin material 36. At this time, the resin material 36 covers the LED chips 21, the protection chips 22, the die mount material 23, and the wires 24, and also wraps around into the portions of the lead frame sheet 33 removed by etching. In a manner described above, the resin material 36 is molded. This molding process is preferably carried out in a vacuum atmosphere. As a result of this, bubbles generated in the resin material 36 can be prevented from adhering to the half-etched portions of the lead frame sheet 33. Next, heat treatment (mold cure) is performed in a state where the top surface of the lead frame sheet 33 is pressed on the resin material 36, and the resin material 36 is cured.

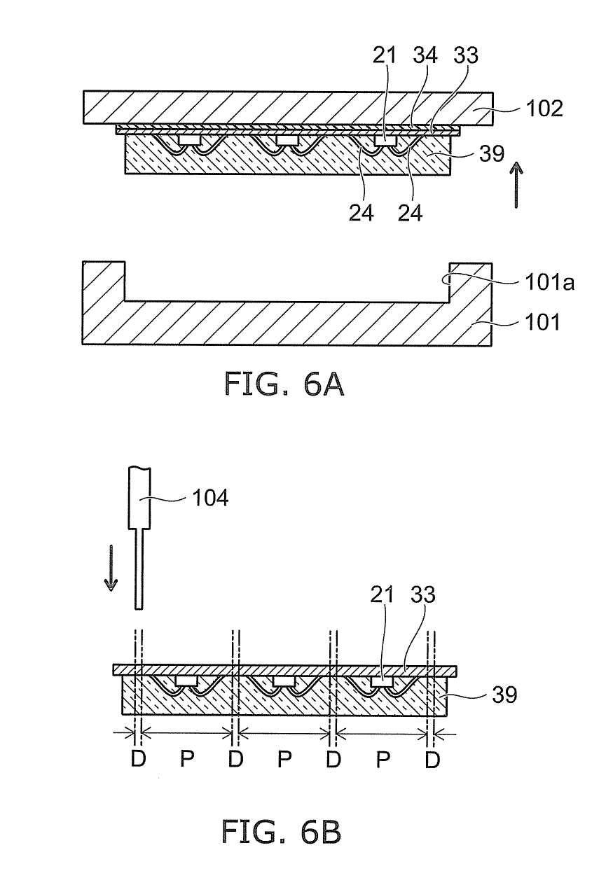

Next, as shown in FIG. 6A, the upper mold 102 is pulled apart from the lower mold 101. As a result of this, formed is a transparent resin plate 39 that covers at least the LED chips 21, the top surface of the lead frame sheet 33, and bottom surfaces of the coupling portions 35. Subsequently, the reinforcing tape 34 is torn off from the lead frame sheet 33. As a result of this, bottom surfaces of the protruding portions of the lead frame are exposed at a surface of the transparent resin plate 39.

Next, as shown in FIGS. 3 and 6B, a combined body comprised of the lead frame sheet 33 and the transparent resin plate 39 is diced from a lead frame sheet 33 side by a blade 104. Namely, it is diced toward the +Z direction. As a result of this, portions arranged in the dicing regions D of the lead frame sheet 33 and the transparent resin plate 39 are removed. Consequently, portions arranged in the element regions P of the lead frame sheet 33 and the transparent resin plate 39 are made into individual pieces, and thereby LED packages are manufactured. It is to be noted that the combined body comprised of the lead frame sheet 33 and the transparent resin plate 39 may be diced from a transparent resin plate 39 side. In addition, although a straight-shaped blade is used as the blade 104 in the embodiment, a taper-shaped blade whose width becomes gradually narrow toward a tip thereof may be used. The taper-shaped blade is used, and thereby a shape of the divided transparent resin body 20 can be a four-sided pyramid trapezoid, thus enabling to improve light extraction efficiency.

In the each LED package after dicing, the respective lead frames 11 to 16 are separated from one another from the lead frame sheet 33. In addition, the transparent resin plate 39 is divided to be the transparent resin body 20. At this time, the support member 30 and portions of a support member 30 side in the each coupling portion 35 are removed, and a remained portion of the coupling portion 35 serves as the extending portion. Additionally, a cut plane of the coupling portion 35, i.e., the tip surface of the each extending portion, is exposed at a side surface of the transparent resin body 20.

Next, as shown in FIG. 3, various kinds of tests are performed with respect to the LED packages. At this time, it is also possible to use the tip surfaces of the extending portions as terminals for the tests.

Next, effects of the embodiment will be described.

In the embodiment, all the chips, i.e., the three LED chips 21R, 21G, and 21B, and the two protection chips 22A and 22B are mounted on the one lead frame 12. Hence, reduction in size of the LED package 1 can be achieved. In addition, the LED package 1 is not provided with an envelope, and also thereby reduction in size can be achieved.

In addition, top surface terminal type chips are used as the protection chips 22A and 22B in the embodiment. As a result of this, the protection chips 22A and 22B can be mounted on the lead frame 12 together with the LED chips 21R, 21G, and 21B, and the protection chips 22A and 22B can be connected to the lead frame other than the lead frame 12. As a result of this, lengths of the wires 24 connected to the protection chips 22A and 22B can be shortened, and thus reliability of the LED package 1 improves.

Further, the LED chips 21R, 21G, and 21B are arranged in a region above the protruding portion 12k of the lead frame 12 in the embodiment. Since a bottom surface of the protruding portion 12k is exposed from the bottom surface of the transparent resin body 20 to be connected to an external wire etc., heat generated in the each LED chip 21 flows through the lead frame 12 to a directly downward direction (−Z direction) to be emitted outside. In addition, as described above, all the LED chips and the protection chips are mounted on the one comparatively large lead frame 12, the comparatively large protruding portion 12k is formed in a region under these chips, and the bottom surface of the protruding portion 12k is exposed from the bottom surface of the transparent resin body 20. As a result of this, a contact area with a mounting substrate on which the LED package 1 is mounted can be increased. Hence, the LED package 1 according to the embodiment has excellent heat radiation performance. In addition, when a potential of a bottom surface terminal of the LED chip 21R is set to be a ground potential, a heat sink can be connected to the bottom surface of the lead frame 12. As a result of this, heat radiation performance further improves.

Still further, in the embodiment, the LED chip 21R is connected between the lead frames 11 and 12, the LED chip 21B is connected between the lead frames 13 and 14, and the LED chip 21G is connected between the lead frames 15 and 16. As a result of this, the lead frames 21R, 21G, and 21B can be mutually independently controlled, and a color tone of light emitted from the LED package 1 can be arbitrarily selected. In addition, the protection chips 22A and 22B are connected in parallel to the LED chips 21B and 21G, respectively, and thereby the LED chips 21B and 21G can be protected.

Still further, each lead frame is provided with the coupling portions 35 extending in the X direction and the coupling portions 35 extending in the Y direction in a wire bonding process shown in FIG. 4D in the embodiment. As a result of this, the lead frame is supported from both the X direction and the Y direction by the support member 30, and thus even though the vibration direction of the ultrasonic waves is any direction in the XY plane, vibration of the lead frame can be suppressed effectively, and the ultrasonic waves can be applied efficiently. Hence, it is not necessary to manage the vibration direction of the ultrasonic waves at the time of wire bonding. Consequently, manufacturing cost of the LED package 1 can be reduced.

Still further, in the embodiment, the coupling portions 35 extending in three directions are formed on the lead frame 12 on which all the chips are mounted. As a result of this, the lead frame 12 is firmly supported from the three directions by the support member 30 in a chip mounting process shown in FIG. 4C and the wire bonding process shown in FIG. 4D. Consequently, the LED package 1 has high chip mounting performance and high wire bonding performance.

Still further, the transparent resin body 20 covers the thin plate portions of the lead frames 11 to 16, i.e., the thin plate portions and the bottom surfaces of the extending portions, and thereby peripheries of the lead frames are held in the embodiment. Hence, holding performance for the lead frames can be enhanced while exposing the bottom surfaces of the protruding portions of the lead frames from the transparent resin body 20 to achieve an external electrode pad. As a result of this, the lead frames 11 to 16 become difficult to be peeled off from the transparent resin body 20 at the time of dicing, thus enabling to improve the yield of the LED package 1. In addition, peeling-off of the lead frames 11 to 16 from the transparent resin body 20 due to temperature stress can be prevented at the time of using the LED package 1.

Still further, the extending portions extend from the bases of the respective lead frames, respectively in the embodiment. As a result of this, the bases themselves are not exposed at the side surfaces of the transparent resin body 20, thus enabling to reduce an exposure area of the lead frames. In addition, a contact area of the lead frames 11 to 16 and the transparent resin body 20 can be increased. Consequently, peeling-off of the lead frames from the transparent resin body 20 can be prevented. In addition, corrosion of the lead frames can also be suppressed.

Still further, the chip side pull-out angle of the wire 24 is smaller than the frame side pull-out angle thereof in the embodiment. As a result of this, a loop of the wire 24 can be formed lower, and thereby a height of the transparent resin body 20 can be reduced. Consequently, a thermal expansion amount and thermal stress of the transparent resin body 20 can be reduced, and thereby fracture of joining portions of the wire 24 due to the thermal stress received from the transparent resin body 20 can be prevented.

Still further, when the transparent resin body 20 expands with heat, thermal stress toward a peripheral upper portion of the transparent resin body 20 acts on the wire 24, and when the transparent resin body 20 contracts with heat, thermal stress toward a central lower portion of the transparent resin body 20 acts on the wire 24. In the embodiment, the portion other than the both ends of the wire 24 is displaced toward the center of the LED package 1 when viewed from the region directly above the straight line connecting these both ends. Hence, when thermal expansion and thermal contraction of the transparent resin body 20 occur, the wire 24 is deformed nearly into a state where it was rotationally moved with the both ends thereof being axes, and therefore it is not easily fractured. In contrast with this, if the portion other than the both ends of the wire 24 is displaced in a direction to move away from the center of the LED package 1, when thermal expansion and thermal contraction of the transparent resin body 20 occur, the wire 24 is deformed nearly into a state where motion of crushing or drawing out the loop thereof was performed, and therefore the wire is easily fractured.

Still further, a large number of, for example, approximately thousands of LED packages can be collectively manufactured from one conductive sheet 31 in the embodiment. As a result of this, manufacturing cost per one LED package can be reduced. In addition, many parts and processes are not needed since no envelope is provided, thus resulting in low cost.

In addition, the lead frame sheet 33 is formed by wet etching in the embodiment. Hence, when manufacturing an LED package with a new layout, it is only necessary to prepare an original of the mask, and initial cost can be suppressed to be lower as compared with a case where the lead frame sheet 33 is formed by a method, such as press by a mold.

Next, a variation of the embodiment will be described.

The variation is the one of a method for forming a lead frame sheet.

Namely, in the variation, a method for forming the lead frame sheet shown in FIGS. 7A and 7B is different from that of the above-described first embodiment.

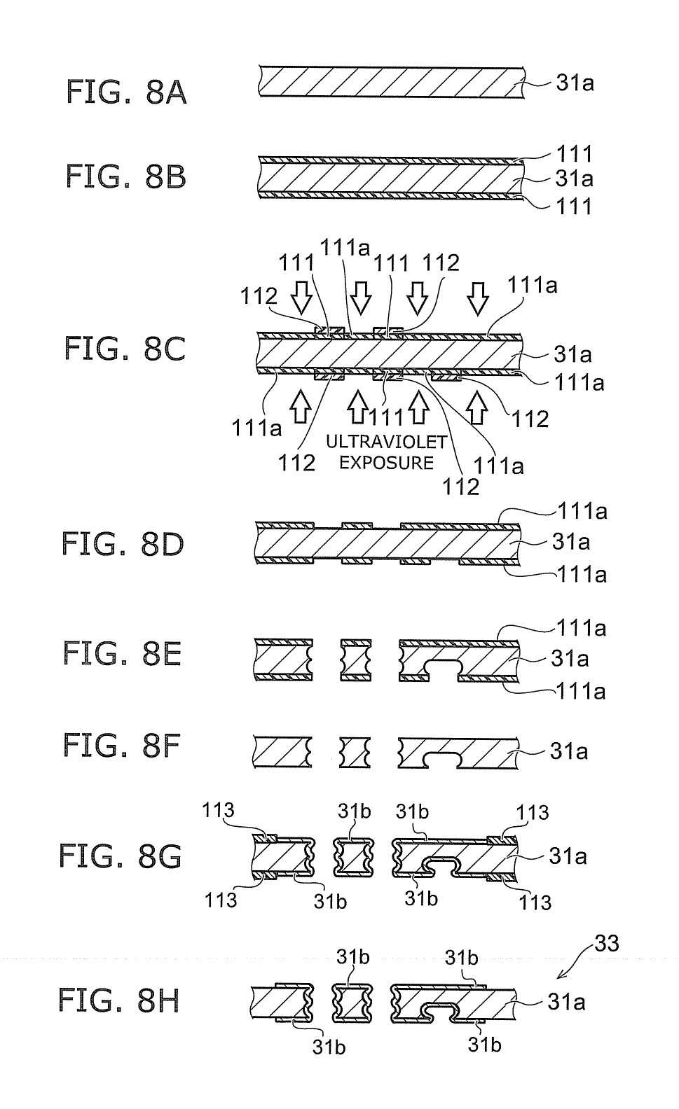

FIGS. 8A to 8H are cross-sectional views of processes illustrating the method for forming the lead frame sheet in the variation.

First, as shown in FIG. 8A, the copper plate 31a is prepared to be cleaned. Next, as shown in FIG. 8B, resist is coated onto both surfaces of the copper plate 31a, and subsequently dried to form resist films 111. Next, as shown in FIG. 8C, mask patterns 112 are arranged on the resist films 111, and they are irradiated with ultraviolet rays to be exposed. As a result of this, exposed portions of the resist films 111 are cured, and thereby resist masks 111a are formed. Next, as shown in FIG. 8D, development is performed, and uncured portions of the resist films 111 are flushed. As a result of this, the resist patterns 111a remain on a top and a bottom surfaces of the copper plate 31a. Next, as shown in FIG. 8E, etching is performed using the resist patterns 111a as masks, and the exposed portions of the copper plate 31a are removed from the both surfaces thereof. At this time, an etched depth is set to be about a half of a plate thickness of the copper plate 31a. As a result of this, regions etched only from one surface side are half-etched, and regions etched from both surface sides are penetrated. Next, as shown in FIG. 8F, the resist patterns 111a are removed. Next, as shown in FIG. 8G, ends of the copper plate 31a are covered with masks 113, and then the copper plate 31a is plated. As a result of this, silver plating layers 31b are formed on surfaces of portions other than the ends of the copper plate 31a. Next, as shown in FIG. 8H, the masks 113 are removed by cleaning. Subsequently, inspections are performed. In a manner described above, the lead frame sheet 33 is fabricated. Configurations, manufacturing methods, and effects other than the above in the variation are similar to those of the above-described first embodiment.

Next, a second embodiment will be described.

FIG. 9 is a plan view illustrating an LED package according to the embodiment.

As shown in FIG. 9, a top surface terminal type LED chip 26R is provided in an LED package 2 according to the embodiment instead of the vertical conduction type LED chip 21R (refer to FIG. 2A) in the LED package 1 according to the first embodiment. The LED chip 26R is the chip that emits red light, and two terminals 26Ra and 26Rb are provided on a top surface thereof. A longitudinal direction of the LED chip 26R and an alignment direction of the terminals 26Ra and 26Rb correspond to the X direction.

In addition, the lead frame 12 (refer to FIG. 2A) of the LED package 1 according to the first embodiment is divided into two lead frames 18 and 19 in the LED package 2 according to the embodiment. In the LED package 2, the lead frame 18 is arranged in a center of the X direction, and the lead frame 19 is arranged at a side end of the +X direction. A shape of the lead frame 19 is a mirror image of the lead frame 11 with respect to the YZ plane that passes through a center of the LED package 2.

Namely, the rectangular portion 12b of the lead frame 12 in the LED package 1 corresponds to a base 18a of the lead frame 18 in the LED package 2, the extending portions 12d and 12f of the lead frame 12 correspond to extending portions 18d and 18f of the lead frame 18, and the protruding portion 12k of the lead frame 12 corresponds to a protruding portion 18k of the lead frame 18. Both sides of the X direction of a portion of the base 18a where the protruding portion 18k is formed are thin plate portions 18t. In addition, the rectangular portion 12c of the lead frame 12 in the LED package 1 corresponds to a base 19a of the lead frame 19 in the LED package 2, the extending portions 12h, 12i, and 12j of the lead frame 12 correspond to extending portions 19b, 19c, and 19d of the lead frame 19, the extending portions 12e and 12g of the lead frame 12 correspond to extending portions 19e and 19f of the lead frame 19, and the protruding portion 12l of the lead frame 12 corresponds to a protruding portion 19l of the lead frame 19. The −X direction side of a portion of the base 19a where a protruding portion 19k is formed is a thin plate portion 19t.

Additionally, the LED chips 21G, 21B, and 26R and the protection chips 22A and 22B are mounted in a region above the protruding portion 18k of the lead frame 18. In addition, a terminal 26Ra of the LED chip 26R is connected to the lead frame 11 through a wire 24a, and a terminal 26Rb is connected to the lead frame 19 through a wire 24j.

According to the embodiment, the lead frame 18 having all the chips mounted thereon gets into an electrically floating state, and thus a heat sink can be connected to the lead frame 18. As a result of this, heat generated in the LED chips can be emitted more efficiently. Configurations, manufacturing methods, and effects other than the above in the embodiment are similar to those of the above-described first embodiment.

Next, a third embodiment will be described.

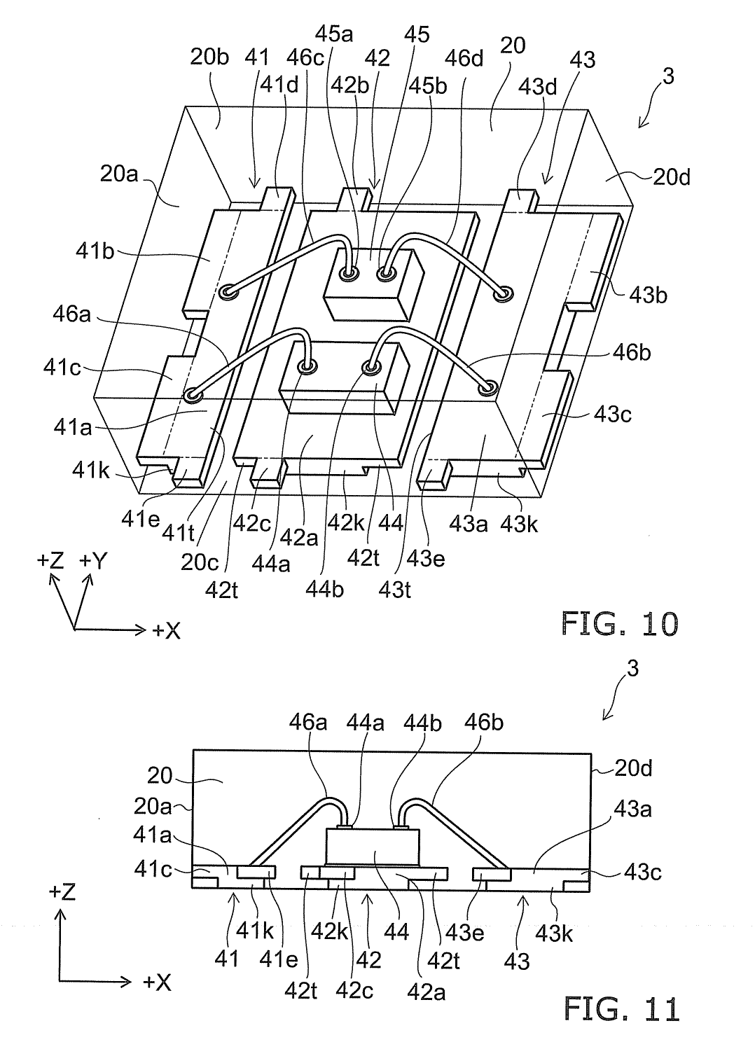

FIG. 10 is a perspective view illustrating an LED package according to the embodiment.

FIG. 11 is a side view illustrating the LED package according to the embodiment.

As shown in FIGS. 10 and 11, three lead frames 41, 42, and 43, one LED chip 44, and one protection chip 45 are provided in an LED package 3 according to the embodiment. Additionally, these are covered with the transparent resin body 20 similarly to the above-described first embodiment. A color tone of light emitted from the LED chip 44 is, for example, blue, but it is not particularly limited to this.

The lead frames 41, 42, and 43 are arranged separated from one another on a same plane, and are aligned in this order toward the +X direction. Additionally, similarly to the above-described first embodiment, each lead frame is provided with one base and a plurality of extending portions, and tip surfaces of the extending portions are exposed at the side surfaces of the transparent resin body 20. In addition, a bottom surface of each base of the each lead frame includes a protruding portion, and a portion of the base where the protruding portion is not formed is a thin plate portion. A bottom surface of the protruding portion is exposed at the bottom surface of the transparent resin body 20, and bottom surfaces of the thin plate portion and the extending portions are covered with the transparent resin body 20.

More specifically, the lead frame 41 is provided with a rectangular-shaped base 41a when viewed from the Z direction and four extending portions 41b to 41e. The extending portions 41b and 41c extend in the −X direction respectively from an end of the +Y direction side and an end of the −Y direction side of an end edge oriented to the −X direction of the base 41a, and tip surfaces of the extending portions 41b and 41c are exposed at the side surface 20a of the transparent resin body 20. The extending portion 41d extends in the +Y direction from an end of the +X direction side of an end edge oriented to the +Y direction of the base 41a, and a tip surface of the extending portion 41d is exposed at the side surface 20b of the transparent resin body 20. The extending portion 41e extends in the −Y direction from an end of the +X direction side of an end edge oriented to the −Y direction of the base 41a, and a tip surface of the extending portion 41e is exposed at the side surface 20c of the transparent resin body 20. In addition, a bottom surface of the base 41a includes a protruding portion 41k which is formed in a region excluding an end of the +X direction side, and the end of the +X direction side of the base 41a is a thin plate portion 41t.

In addition, the lead frame 42 is provided with a rectangular-shaped base 42a when viewed from the Z direction and two extending portions 42b and 42c. The extending portion 42b extends in the +Y direction from a portion of the −X direction side of an end edge oriented to the +Y direction of the base 42a, and a tip surface of the extending portion 42b is exposed at the side surface 20b of the transparent resin body 20. The extending portion 42c extends in the −Y direction from a portion of the −X direction side of an end edge oriented to the −Y direction of the base 42a, and a tip surface of the extending portion 42c is exposed at the side surface 20c of the transparent resin body 20. In addition, a bottom surface of the base 42a includes a protruding portion 42k which is formed in a region excluding both ends of the X direction, and the other regions, i.e., both ends of the X direction of the base 42a are thin plate portions 42t. In other words, the protruding portion 42k is formed in a region separated from both an end edge opposed to the lead frame 41 and an end edge opposed to the lead frame 43 on the bottom surface of the lead frame 42.

Further, the lead frame 43 is provided with a rectangular-shaped base 43a when viewed from the Z direction and four extending portions 43b to 43e. The extending portions 43b and 43c extend in the +X direction respectively from an end of the +Y direction side and an end of the −Y direction side of an end edge oriented to the +X direction of the base 43a, and tip surfaces of the extending portions 43b and 43c are exposed on the side surface 20d of the transparent resin body 20. The extending portion 43d extends in the +Y direction from an end of the −X direction side of the end edge oriented to the +Y direction of the base 43a, and a tip surface of the extending portion 43d is exposed at the side surface 20b of the transparent resin body 20. The extending portion 43e extends in the −Y direction from an end of the −X direction side of an end edge oriented to the −Y direction of the base 43a, and a tip surface of the extending portion 43e is exposed at the side surface 20c of the transparent resin body 20. In addition, a bottom surface of the base 43a includes a protruding portion 43k which is formed in a region excluding an end of the −X direction side, and the end of the −X direction side of the base 43a is a thin plate portion 43t.

The LED chip 44 and the protection chip 45 are mounted on the lead frame 42, and they are arranged in a region above the protruding portion 42k. The LED chip 44 is arranged closer to the −Y direction side than a center of the LED package 3, and the protection chip 45 is arranged closer to the +Y direction side than the center of the LED package 3. Both the LED chip 44 and the protection chip 45 are the top surface terminal type chips, and two terminals are provided on top surfaces thereof, respectively. An alignment direction of the terminal in each chip is the X direction. One terminal 44a of the LED chip 44 is connected to a portion of the −Y direction side of the lead frame 41 through a wire 46a, and the other terminal 44b is connected to a portion of the −Y direction of the lead frame 43 through a wire 46b. One terminal 45a of the protection chip 45 is connected to a portion of the +Y direction side of the lead frame 41 through a wire 46c, and the other terminal 45b is connected to a portion of the +Y direction of the lead frame 43 through a wire 46d. As described above, the protection chip 45 is connected in parallel to the LED chip 44.

According to the embodiment, similarly to the above-described second embodiment, the lead frame 42 having the LED chip 44 and the protection chip 45 mounted thereon gets into an electrically floating state, and thus a heat sink can be connected to the lead frame 42. As a result of this, heat generated in the LED chip 44 can be efficiently emitted. Configurations, manufacturing methods, and effects other than the above in the embodiment are similar to those of the above-described first embodiment.

It is to be noted that in the embodiment shown is an example in which a chip side pull-out angle of the each wire 46 is larger than a frame side pull-out angle thereof, but it is not limited to this, and the chip side pull-out angle may be smaller than the frame side pull-out angle as in the above-described first embodiment.

Next, a fourth embodiment will be described.

FIG. 12A is a plan view illustrating lead frames, LED chips, and wires of an LED package according to the embodiment, FIG. 12B is a bottom surface view illustrating the LED package, and FIG. 12C is a cross-sectional view illustrating the LED package.

As shown in FIGS. 12A to 12C, the embodiment is an example in which four LED chips and one protection chip are connected in parallel to one another in the LED package in which three lead frames are provided.

Namely, an LED package 4 according to the embodiment is provided with three lead frames 61, 62, and 63 separated from one another. In the lead frame 61, a extending portion 61b extends in the +Y direction, a extending portion 61c extends in the −Y direction, and two extending portions 61d and 61e extend in the −X direction from a strip-shaped base 61a whose longitudinal direction corresponds to the Y direction. In the lead frame 62, two extending portions 62b and 62c extend in the +Y direction, and two extending portions 62d and 62e extend in the −Y direction from a strip-shaped base 62a whose longitudinal direction corresponds to the Y direction. Although a shape of the lead frame 63 is nearly the one of the reversed lead frame 61 in the X direction, extending portions 63d and 63e are narrower than the extending portions 61d and 61e.

A protruding portion 61k is formed in a region excluding an end of the +X direction side on a bottom surface of the base 61a includes a protruding portion 61k which is formed in a region excluding an end of the +X direction side, and the end of the +X direction side of the base 61a is a thin plate portion 61t. Similarly, a protruding portion 63k is formed in a region excluding an end of the −X direction side on a bottom surface of a base 63a, and the end of the −X direction side of the base 63a is a thin plate portion 63t. Meanwhile, a protruding portion 62k is formed in a region excluding both ends of the X direction on a bottom surface of the base 62a, and the both ends of the X direction of the base 62a are thin plate portions 62t. Namely, the protruding portion 62k having the chips mounted thereon is formed in a region separated from both an end edge opposed to the lead frame 61 and an end edge opposed to the lead frame 63 on the bottom surface of the lead frame 62.

In addition, the LED package 4 is provided with four LED chips 67 and one protection chip 68. The four LED chips 67 are the chips mutually based on a same standard, and mutually emit same color light, for example, white light. In addition, a Zener diode is formed on the protection chip 68. The four LED chips 67 and the one protection chip 68 are mounted on a center of the X direction of the lead frame 62 through a die mount material (not shown), and are aligned in a line along the Y direction in a region above the protruding portion 62k. The protection chip 68 is aligned the closest to the +Y direction side. One terminal of the each chip is connected to the lead frame 61 through a wire 65a, and the other terminal thereof is connected to the lead frame 63 through a wire 65b.

According to the present embodiment, since the four LED chips 67 are provided in one LED package, large amount of light can be obtained. In addition, similarly to the above-described second and third embodiments, all the chips are mounted on the lead frame 62, and are connected between the lead frames 61 and 63, thereby enabling the lead frame 62 to be in an electrically floating state. As a result of this, an electrically independent heat sink can be obtained. Configurations, manufacturing methods, and effects other than the above in the embodiment are similar to those of the above-described first embodiment.

According to the above-described embodiments, the LED package whose size is easily reduced can be achieved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

For example, grooves may be formed in regions between the LED chips on top surfaces of the lead frames having the LED chips mounted thereon. As a result of this, wrapping around of the die mount material can be prevented, and variation in mounting positions of the LED chips can be reduced.

Further, although in the above-described each embodiment and the modified example thereof, have been shown the examples in which the shape of the base of the lead frame is the rectangle when viewed from above, the shape of the base may be the one in which at least one corner is rounded off. As a result of this, corners of a right angle or an acute angle are removed near corners of the LED package, and thus these corners do not serve as base points of resin peeling or cracks. As a result of this, resin peeling and occurrence of cracks of the whole LED package can be suppressed.

What is claimed is:

1. An LED package comprising:
a first, a second, and a third lead frame separated from one another;
a first LED chip of a top surface terminal type having one terminal connected to the second lead frame, and having one other terminal connected to the third lead frame, the first LED chip being mounted on the first lead frame;
a first protection chip of a top surface terminal type having one terminal connected to the second lead frame, and having one other terminal connected to the third lead frame, the first protection chip being mounted on the first lead frame; and
a resin body covering a part of the first, second and third lead frames, the first LED chip, and the first protection chip,
an outer shape of the resin body forming an outer shape of the LED package.

2. The package according to claim 1, further comprising:
a fourth and a fifth lead frame separated from the first, second, and third lead frames, and separated from each other;
a second LED chip of a top surface terminal type having one terminal connected to the fourth lead frame, and having one other terminal connected to the fifth lead frame, the second LED chip being mounted on the first lead frame; and
a second protection chip of a top surface terminal type having one terminal connected to the fourth lead frame, and having one other terminal connected to the fifth lead frame, the second protection chip being mounted on the first lead frame.

3. The package according to claim 2, further comprising:
a sixth lead frame separated from the first, second, third, fourth, and fifth lead frames; and
a third LED chip of a vertical conduction type having a bottom surface terminal connected to the first lead frame, and having a top surface terminal connected to the sixth lead frame, the third LED chip being mounted on the first lead frame.

4. The package according to claim 3, wherein the first LED chip is a blue LED chip emitting blue light, the second LED chip is a green LED chip that emits green light, and the third LED chip is a red LED chip that emits red light.

5. The package according to claim 2, further comprising:
a sixth and a seventh lead frame separated from the first, second, third, fourth, and fifth lead frames, and separated from each other; and
a fourth LED chip of a top a surface terminal type having one terminal connected to the sixth lead frame, and having one other terminal connected to the seventh lead frame, the fourth LED chip being mounted on the first lead frame.

6. The package according to claim 5, wherein the first LED chip is a blue LED chip emitting blue light, the second LED chip is a green LED chip that emits green light, and the fourth LED chip is a red LED chip that emits red light.

7. The package according to claim 1, further comprising:
a fifth LED chip of a top surface terminal type having one terminal connected to the second lead frame, and having one other terminal connected to the third lead frame, the fifth LED chip being mounted on the first lead frame.

8. The package according to claim 7, wherein a color of light emitted from the fifth LED chip is same as a color of light emitted from the first LED chip.

9. The package according to claim 1, wherein the first protection chip is a Zener diode.

10. The package according to claim 1, wherein a bottom surface of the first lead frame includes a protruding portion, a bottom surface of the protruding portion is exposed on a bottom surface of the resin body, and the first LED chip and the first protection chip are mounted on a top surface of the first lead frame in a region above the protruding portion.

11. The package according to claim 10, wherein
the bottom surface of the first lead frame includes an first end edge which is opposed to the second lead frame, and a second end edge which is opposed to the third lead frame, and the protruding portion is formed in a region separated from the first end edge and the second end edge.

12. The package according to claim 1 wherein
each of the first, second, and third lead frames has:
a first plate portion whose top surface and side surface are covered with the resin body and bottom surfaces is exposed on bottom surface of the resin body; and
a second plate portion which is thinner than the first plate portion, the second plate portion having top surface and bottom surface covered with the resin body, and the second plate portion having side surface, whose first part is covered with the resin body and second part is exposed on side surface of the resin body.

13. The package according to claim 12, wherein
the first, second, and third lead frames are provided on one plane;
each of the second plate portions of the second and third lead frames includes three extending portions, each of the three extending portions extends from the first plate portion in directions different from one another.
